(19) United States
(12) Patent Application Publication
(10) Pub. No.: US 2024/0170309 A1
(43) Pub. Date: May 23, 2024

(54) SEMICONDUCTOR TOOL ARRANGEMENTS

(71) Applicant: Lam Research Corporation, Fremont, CA (US)

(72) Inventor: Karl Frederick Leeser, West Linn, OR (US)

(21) Appl. No.: 18/283,797

(22) PCT Filed: Apr. 27, 2022
(86) PCT No.: PCT/US2022/026544

§ 371 Date: Sep. 23, 2023

Related U.S. Application Data
(60) Provisional application No. 63/181,036, filed on Apr. 28, 2021.

(51) Int. Cl. H01L 21/67

(52) U.S. Cl. CPC H01L 21/6719; H01L 21/67167; H01L 21/67196; H01L 21/67201

(57) ABSTRACT

Various examples include arrangements of semiconductor-processing tools. In one example, a semiconductor-processing tool includes multiple multi-station modules, each having multiple processing stations. At least some of the processing stations are organized in a diamond-shaped arrangement. A vacuum-transfer module is coupled to each of the multi-station modules. The vacuum-transfer module has one or more vacuum-transfer robots to transfer substrates to and from at least one of the multiple processing stations. At least one additional processing-station is located in the vacuum-transfer module. Other systems and apparatuses are disclosed.

### CLAIM OF PRIORITY

This application claims the benefit of priority to U.S. Provisional Patent Application Ser. No. 63/181,036, filed on Apr. 28, 2021, which is incorporated by reference herein in its entirety.

### TECHNOLOGY FIELD

The disclosed subject matter is related generally to the field of substrate-processing tools used in the semiconductor and allied industries (e.g., flat-panel display and solar-cell production facilities). More specifically, in various embodiments, the disclosed subject matter is related to an arrangement of substrate-processing tools used to reduce a footprint of the tool while maintaining a large number of processing stations within the tool.

### BACKGROUND

Semiconductor capital equipment is evaluated on many performance metrics. Two metrics are productivity and footprint. Productivity can relate to substrate throughout and yield. The footprint is related to the area consumed by a production tool within a fabrication environment (fab).

The background description provided here is for the purpose of generally presenting the context of the disclosed subject matter. Work of the presently named inventors, to the extent that it is described in this background section, as well as aspects of the description that may not otherwise qualify as prior art at the time of filing, are neither expressly nor impliedly admitted as prior art against the present disclosure. Consequently, the information described in this section is provided to offer the skilled artisan a context for the following disclosed subject matter and should not be considered as admitted prior art. The information described in this section is therefore provided to offer the skilled artisan a context for the following disclosed subject matter and should not be considered as admitted prior art.

### SUMMARY

In various embodiments, a semiconductor-processing tool includes multiple multi-station modules, each having multiple processing stations. At least some of the processing stations are organized in a diamond-shaped arrangement. A vacuum-transfer module is coupled to each of the multi-station modules. The vacuum-transfer module has one or more vacuum-transfer robots to transfer substrates to and from at least one of the multiple processing stations. The semiconductor-processing tool also includes at least one additional processing-station located in the vacuum-transfer module.

In various embodiments, a semiconductor-processing tool includes multiple multi-station modules, each having multiple processing stations. At least some of the processing stations are organized in a diamond-shaped arrangement. A vacuum-transfer module is coupled to each of the multi-station modules. The vacuum-transfer module has one or more vacuum-transfer robots to transfer substrates to and from at least one of the multiple processing stations. At least one additional processing-station is located in the vacuum-transfer module.

In various embodiments, a semiconductor-processing tool includes multiple multi-station modules. A hybrid-arrangement of multiple processing stations with at least some of the processing stations organized in a diamond-shaped arrangement and a remaining portion of the processing stations is organized in a square-shaped arrangement. A vacuum-transfer module is coupled to each of the multi-station modules. The vacuum-transfer module has one or more vacuum-transfer robots to transfer substrates to and from at least one of the multiple processing stations. The semiconductor-processing tool also includes at least one additional processing-station located in the vacuum-transfer module.

### BRIEF DESCRIPTION OF FIGURES

FIG. 1 shows a cut-away plan view of a multi-station, semiconductor-processing tool of the prior art having a square arrangement of processing stations;

FIG. 2A shows an exemplary embodiment of a cut-away plan view of a multi-station, semiconductor-processing tool having a diamond-shaped arrangement of processing stations within each of five modules in accordance with embodiments of the disclosed subject matter;

FIG. 2B shows an exemplary embodiment of a cut-away plan view of a multi-station, semiconductor-processing tool having a diamond-shaped arrangement of processing stations within each of four modules in accordance with embodiments of the disclosed subject matter;

FIGS. 2C through 2H show various examples of processing-station arrangements within a processing module, which are in accordance with various embodiments of the disclosed subject matter;

FIG. 3A shows an exemplary embodiment of a cut-away plan view of a multi-station, semiconductor-processing tool having a square-shaped arrangement of processing stations, including additional processing-stations located within a vacuum-transfer module, in accordance with embodiments of the disclosed subject matter;

FIG. 3B shows an exemplary embodiment of a cut-away plan view of a multi-station, semiconductor-processing tool having a diamond-shaped arrangement of processing stations, including additional processing-stations located within a vacuum-transfer module, in accordance with embodiments of the disclosed subject matter;

FIG. 3C shows an exemplary embodiment of a cut-away plan view of a multi-station, semiconductor-processing hybrid tool having both square-shaped and diamond-shaped arrangements of processing stations, including additional processing-stations located within a vacuum-transfer module, in accordance with embodiments of the disclosed subject matter;

FIG. 4A shows an exemplary embodiment of a semiconductor-processing tool that includes a dual-level load-lock and transfer station, which is in accordance with embodiments of the disclosed subject matter;

FIG. 4B shows an exemplary embodiment of a semiconductor-processing tool that includes a tandem, dual-level load-lock and transfer station, which is in accordance with embodiments of the disclosed subject matter;

FIG. 4C shows an exemplary embodiment of a semiconductor-processing tool indicating substrate transfer-paths on different levels, which is in accordance with various embodiments of the disclosed subject matter;

FIG. 5A shows an example of dimensions comprising a typical footprint of the semiconductor-processing tool of FIG. 1;

FIGS. 5B and 5C show examples of dimensions comprising a footprint some of the tool arrangements discussed in accordance with various embodiments of the disclosed subject matter as provided in certain examples of FIG. 2A through FIG. 4B; and

FIGS. 6A and 6B show exemplary plan view and elevational views, respectively, of an atmospheric transfer-robot that is compatible with a reduced-depth equipment front-end module (EFEM), which may be used with various embodiments of the disclosed subject matter.

### DETAILED DESCRIPTION

The description that follows includes illustrative examples, devices, and apparatuses that embody various aspects of the disclosed subject matter. In the following description, for purposes of explanation, numerous specific details are set forth in order to provide an understanding of various embodiments of the inventive subject matter. It will be evident however, to those of ordinary skill in the art, that various embodiments of the disclosed subject matter may be practiced without these specific details. Further, well-known structures, materials, and techniques have not been shown in detail, so as not to obscure the various illustrated embodiments. As used herein, the terms “about” or “approximately” may refer to values that are, for example, within +10% of a given value or range of values.

Multi-station, semiconductor-processing tools of the prior art have always included processing stations that are arranged in a square, x-y arrangement (when considered from a top, plan-view of the tool) with reference to a proximal sidewall of the tools. This x-y arrangement is discussed in more detail below. However, these arrangements are limited in the amount of areal reduction that can occur.

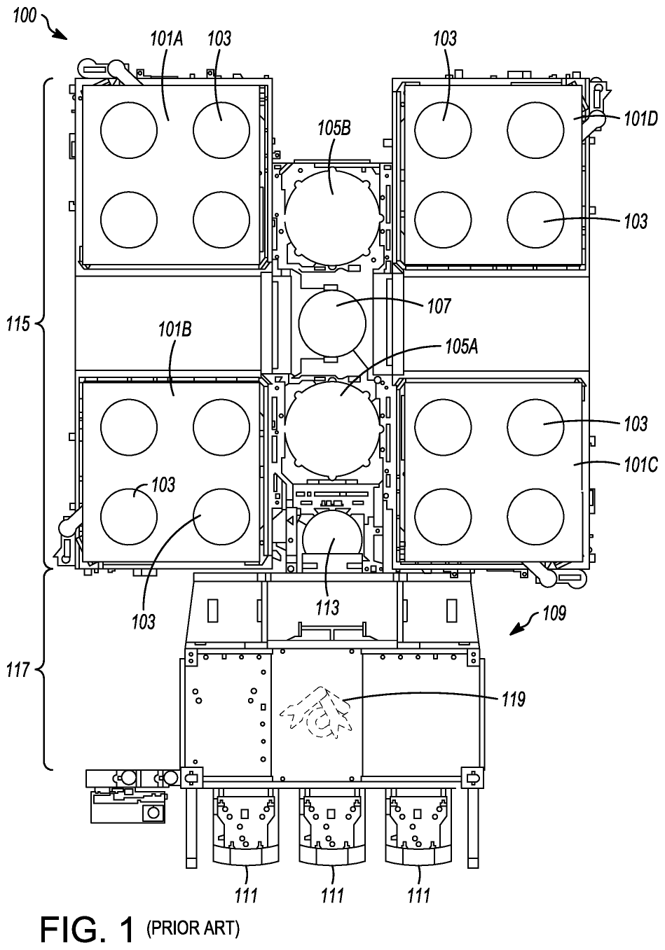

For example, with reference to FIG. 1, a high-level overview of a cut-away plan view of a multi-station, semiconductor-processing tool 100 of the prior art is shown. The semiconductor-processing tool 100 has a square-shaped arrangement of processing stations 103 as described in more detail below. The semiconductor-processing tool 100 also includes a processing portion 115 and an equipment front-end module (EFEM) 115. While the semiconductor-processing tool 100 is in operation, the processing portion 115 is typically operated at less than atmospheric pressure (e.g., low-vacuum levels of a few Torr or lower).

Within the processing portion 115, the semiconductor-processing tool 100 includes four, quad-station modules 101A, 101B, 101C, 101D. Each of the quad-station modules 101A-101D includes four of the processing stations 103. Although other numbers of processing stations are possible, the example is included to help illustrate significant differences between the semiconductor-processing tool 100 of the prior art and the disclosed subject matter, described herein. Each of the processing stations 103 is arranged to hold a single substrate (e.g., a 300 mm semiconductor wafer) during a processing operation (e.g., a chemical-vapor deposition process or an atomic-layer deposition process). In this specific example, each of the quad-station modules 101A-101D is approximately 1.1 meters in dimension along each edge. Additional dimensions of the overall semiconductor-processing tool are described in more detail, below.

Each pair of the processing stations 103 is either parallel or perpendicular to a sidewall of the semiconductor-processing tool 100. For example, the sidewall may be considered to be located between vacuum-transfer robots 105A, 105B and a respective one of the quad-station modules 101A-101D (in which the respective pairs of processing stations 103 is located). Therefore, an arrangement of the processing stations 103 is considered to be a square-shaped arrangement.

With continuing reference to FIG. 1, each of the substrates is loaded into the semiconductor-processing tool 100 by an atmospheric transfer-robot (ATR) 119 located within the EFEM 117. The ATR 119 loads at least a single substrate at a time from one of a plurality of substrate carriers 111 onto a first transfer station 113. As shown in FIG. 1, the ATR 119 has two arms and can load up to two substrate at a time onto the first transfer station 113. Each of the substrate carriers 111 may comprise, for example, a front-opening unified pod (FOUP) or other type of standard mechanical interface (SMIF)) substrate container known in the art. Once the ATR 119 loads the substrate onto the first transfer station 113, an atmospheric port (not shown explicitly) located between the EFEM 117 and the first transfer station 113 is closed. A load lock area surrounding the first transfer station 113 is pumped down to a vacuum level at or near the processing portion 115.

The semiconductor-processing tool 100 also includes a first vacuum-transfer robot (VTR) 105A and a second VTR 105B. Each of the vacuum-transfer robots 105A, 105B can be considered to be a substrate-handling robot to move substrates within the processing portion 115. For example, the first VTR 105A can move a substrate from the first transfer station 113 to any one of the processing stations 103 within the quad-station modules 101B, 101C closest to the EFEM 117 (front of the tool), or to a second transfer station 107. The second VTR 105B can move a substrate from the second transfer station 107 to any one of the processing stations 103 within the quad-station modules 101A, 101D, which are most distal from the EFEM 117 (most distal meaning located near the top of the page or at the rear of the tool).

As shown in FIG. 1, the EFEM 117 also includes a bump-out region 109 that occupies a significant area. The bump-out region 109 is added such that a maintenance technician can access portions of the semiconductor-processing tool 100. However, the bump-out region 109 itself adds a significant amount of area to the semiconductor-processing tool 100 (thus increasing the overall footprint of the tool).

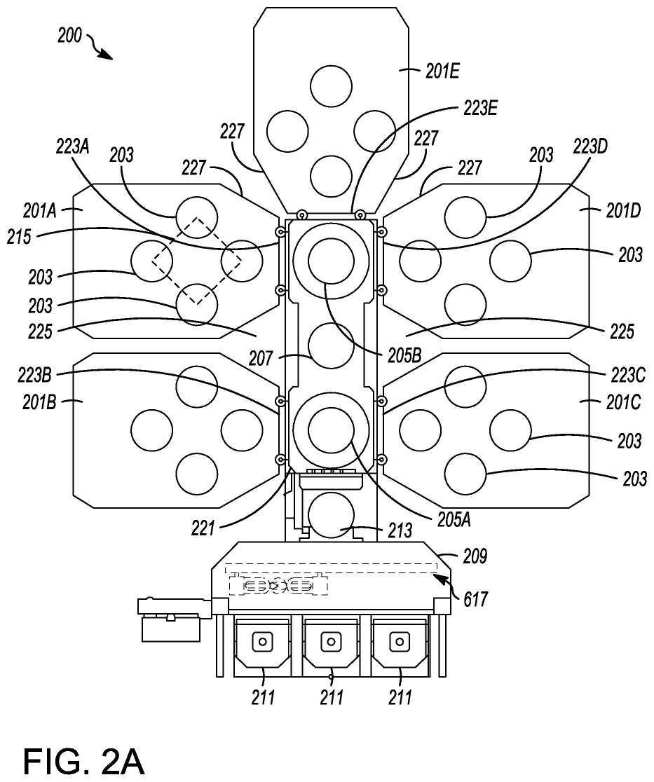

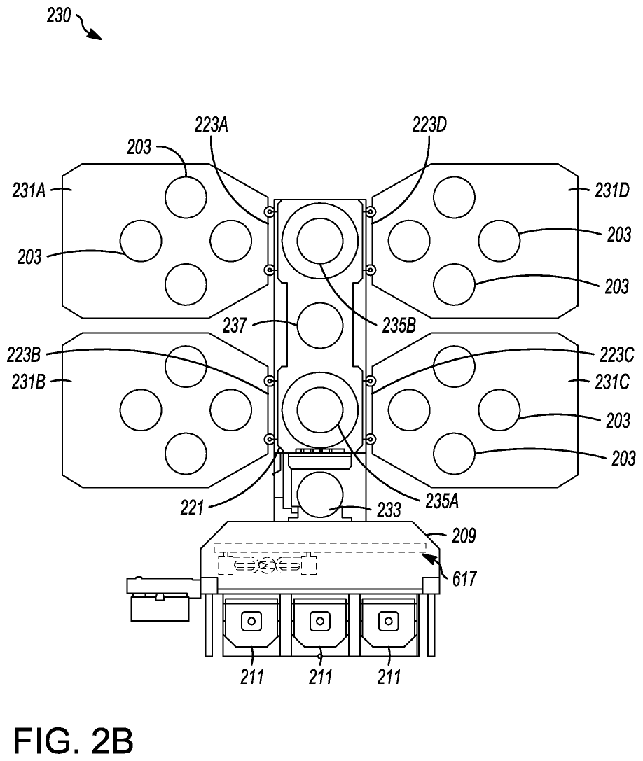

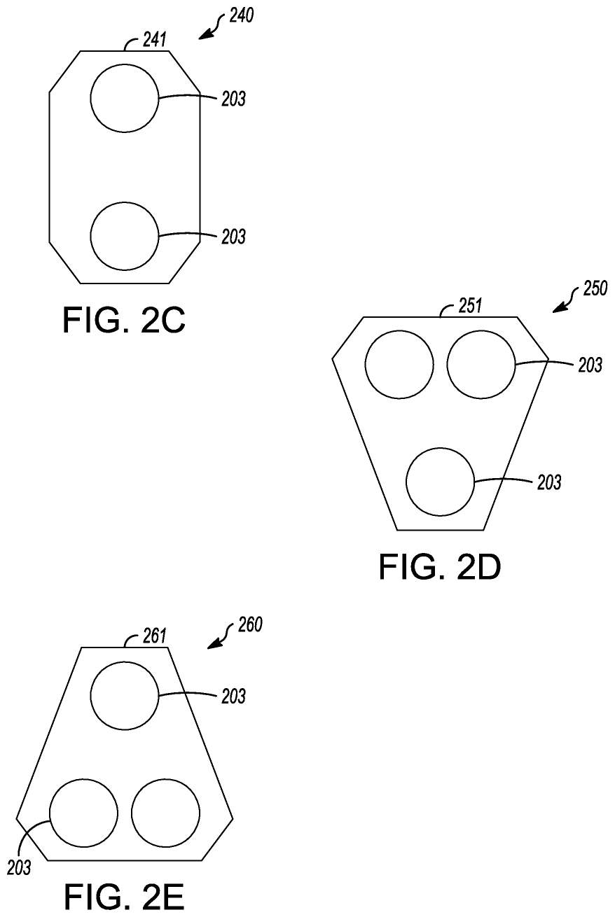

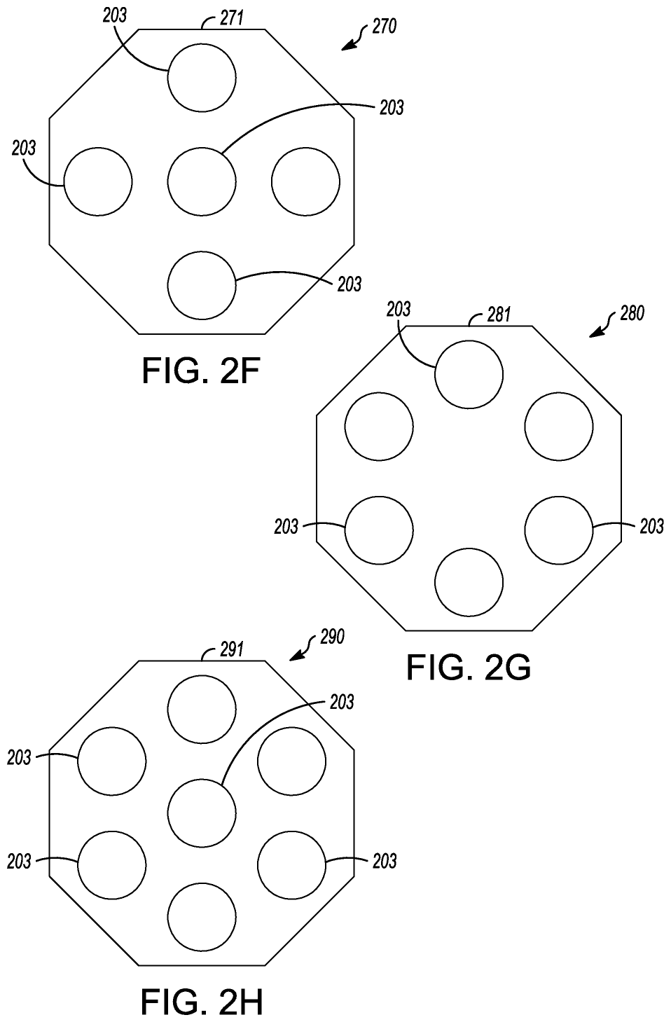

With reference now to FIG. 2A, an exemplary embodiment of a cut-away plan view of a multi-station, semiconductor-processing tool 200 is shown. The semiconductor-processing tool 200 is shown to include a diamond-shaped arrangement 215 of processing stations 203 in accordance with embodiments of the disclosed subject matter. The semiconductor-processing tool 200 is also shown to include a vacuum-transfer module 221, containing a front vacuum-transfer robot (VTR) 205A, more proximate a first transfer station 213, and a rear VTR 205B, located at the rear of the semiconductor-processing tool 200. The semiconductor-processing tool 200 is also shown to include a second transfer station 207. The skilled artisan will appreciate that the front VTR 205A and the rear VTR 205B are depicted schematically as circles so as not to obscure other components of the disclosed subject matter. As shown, a chamber transfer-port 223A-223E (or vacuum gate) is located between the vacuum-transfer module 221 and each multi-station module 201A-201E.

Although five of the multi-station modules 201A-201E are shown in FIG. 2A, no limitation to five modules should be implied. More or fewer than five of the multi-station modules 201A-201E can be implemented. For example, two, three, four, six, seven, or more modules can be included in the semiconductor-processing tool 200. Further, more than or fewer than four processing stations 203 can be included within each of the modules. For example, two, three, five, or more processing stations may be included in certain embodiments. Moreover, not all of the modules need to include the same number of processing stations. Some of the modules may include one or two processing stations while other modules may include five or more processing stations. The various processing-station arrangements are discussed below with reference to FIGS. 2C through 2H. Therefore, five of the multi-station modules 201A-201E, each with four processing stations 203 are shown merely as an aid in describing the disclosed subject matter.

The diamond-shaped arrangement 215 indicates that the processing stations 203 are placed at an angle with regard to a respective one of the chamber transfer-ports 223A-223E located on each of the multi-station modules 201A-201E. The respective chamber transfer-ports 223A-223E allow a substrate to be placed by the front VTR 205A or the rear VTR 205B onto various ones of the processing stations 203 within the multi-station modules 201A-201E. After all substrates are placed on various ones of the processing stations 203 (e.g., from the first transfer station 213 or the second transfer station 207), an appropriate one of the chamber transfer-ports 223A-223E is closed to prevent any gases, plasma, etc. from passing from one multi-station module to another or from one multi-station module into the vacuum-transfer module 221.

In an embodiment, an angle of one side of the diamond-shaped arrangement 215 may be, for example, about 45° with reference to the respective chamber transfer-port 223A-223E. In other embodiments, the angle of one side of the diamond-shaped arrangement 215 may be, for example, from about 30° to about 60° with reference to the respective chamber transfer-port 223A-223E. In other embodiments, the angle of one side of the diamond-shaped arrangement 215 may be, for example, from about 15° to about 75° with reference to the respective chamber transfer-port 223A-223E. In other embodiments, the diamond-shaped arrangement 215 may comprise, for example, a rhombus having angles between adjacent sides greater than 90° and less than 90°. Upon reading and understanding the disclosed subject matter, a person of ordinary skill in the art will recognize that other geometries (e.g., a rhomboid) are also possible. Each of the various angles and angular ranges may be considered with regard to various processing-station arrangements within a processing module. The various processing-station arrangements are also discussed below with reference to FIGS. 2C through 2H.

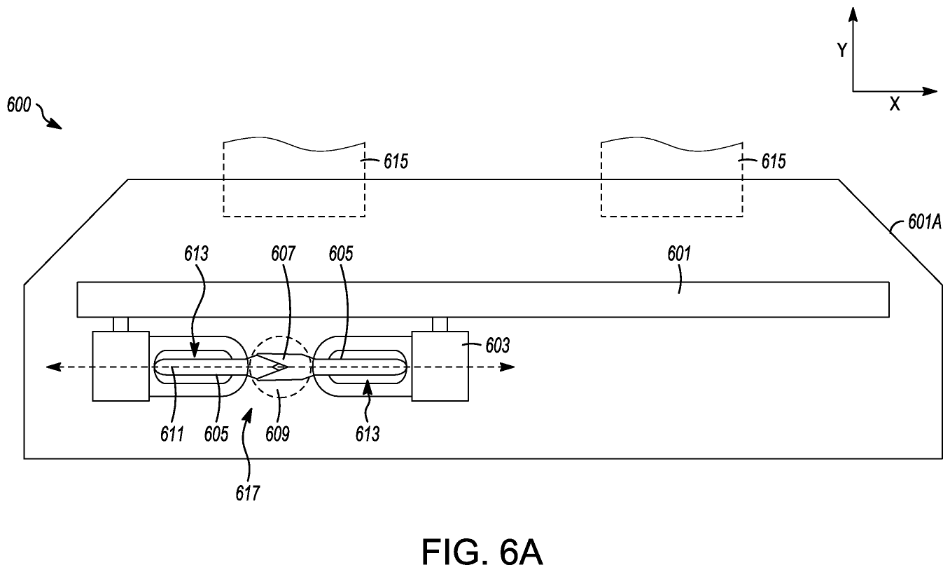

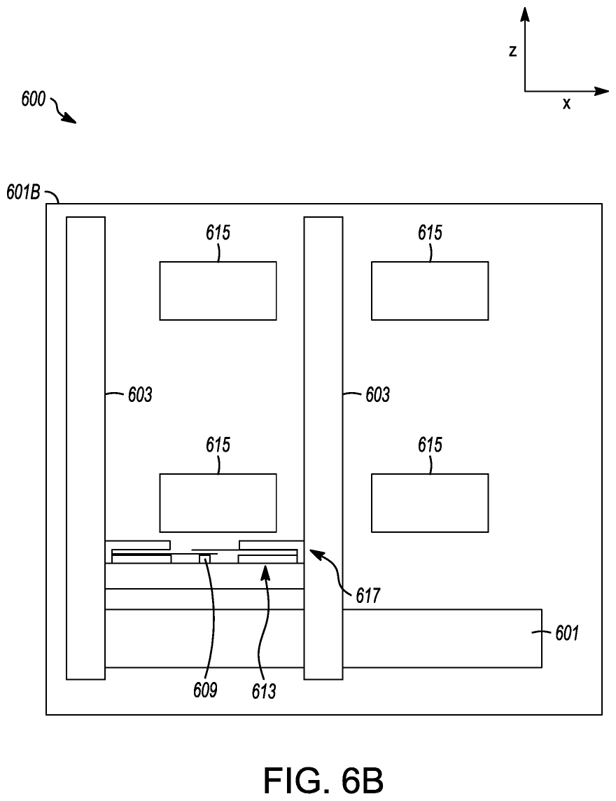

Each of the substrates is loaded into the semiconductor-processing tool 200 by a linear atmospheric transfer-robot (ATR) 617 located within a reduced-depth EFEM 209. The linear ATR 617 is described in detail with reference to FIGS. 6A and 6B, below. The linear ATR 617 loads at least one substrate at a time from one of a plurality of substrate carriers 211 onto the first transfer station 213. As with the semiconductor-processing tool 100 of FIG. 1, each of the substrate carriers 111 may comprise, for example, a front-opening unified pod (FOUP) or other type of standard mechanical interface (SMIF)) substrate container known in the art.

The reduced-depth EFEM 209 serves to reduce an overall footprint of the semiconductor-processing tool 200. A comparison of FIG. 1 with, for example, FIG. 2A, indicates that the bump-out region 109 of FIG. 1 has been removed. Instead, the linear ATR 617 is placed within the reduced-depth EFEM 209. The reduced-depth EFEM 209 allows for a maintenance technician to still access all areas proximate to the reduced-depth EFEM 209 for repair or maintenance. The steeper angle of the reduced-depth EFEM 209 (on a side opposite the substrate carriers 211) allows access to each of the substrate carriers 211, even from the front VTR 205A.

In certain embodiments, a maintenance-aperture feature 225 located between one or more of the multi-station modules 201A-201E allows access to various locations within and beneath adjacent ones of the modules. The maintenance-aperture feature 225 may be open, as shown, or include a cover plate. Although a single one of the maintenance-aperture features 225 is shown located between each of the multi-station modules 201A, 201B and the multi-station modules 201C, 201D, more or fewer of the maintenance-aperture features 225 may be located in different locations within a given processing tool. Upon reading and understanding the disclosed subject matter, a person of ordinary skill in the art will recognize where such a maintenance-aperture feature 225 may be located (e.g., in other embodiments shown in FIGS. 2B-4B).

With continuing reference to FIG. 2A, a person of ordinary skill in the art will recognize that, based on the diamond-shaped arrangement 215 of the processing stations 203, adjacent ones of the multi-station modules 201A-201E may be placed in closer proximity to one another than the quad-station modules 101A-101D of FIG. 1. That is, the diamond-shaped arrangement 215 allows a portion of the modules to have an angled outer-surface 227. The angled outer-surface 227 allows the modules to have an increased packing density—the multi-station modules 201A-201E may be placed together in a smaller footprint while still including the same number of the processing stations 203 in each module.

Referring now to FIG. 2B, an exemplary embodiment of a cut-away plan view of a multi-station, semiconductor-processing tool 230 is shown. The semiconductor-processing tool 200 is shown to include a front vacuum-transfer robot (VTR) 235A, more proximate a first transfer station 233, and a rear VTR 235B, located at the rear of the semiconductor-processing tool 230. The front VTR 235A and the rear VTR 235B may the same as or similar to the vacuum-transfer robots 205A, 205B of FIG. 2A. The skilled artisan will appreciate that the front VTR 235A and the rear VTR 235B are depicted schematically as circles so as not to obscure other components of the disclosed subject matter. Also, a second transfer station 237 is shown. Similar to the description above with reference to FIG. 2A, after substrates are placed on various ones of the processing stations 203 (e.g., from the first transfer station 233 or the second transfer station 237), an appropriate one of the chamber transfer-ports 223A-223D is closed to prevent any gases, plasma, etc. from passing from one multi-station module to another.

Consequently, the semiconductor-processing tool 230 is the same as or similar to the semiconductor-processing tool 200 of FIG. 2A. However, in the embodiment of FIG. 2B, there are only four of the multi-station modules 231A-231D, rather than five as shown in FIG. 2A. Consequently, the skilled artisan will recognize that any number of modules may be included and still remain within a scope of the disclosed subject matter.

FIGS. 2C through 2H show various examples of processing-station arrangements within a processing module, which are in accordance with various embodiments of the disclosed subject matter. As is understood by a skilled artisan, patent drawings are not drawn to scale. Therefore, a person of ordinary skill in the art will recognize that the width and/or the length of each of the processing-station arrangements may be changed as needed to suit a particular processing tool. The skilled artisan will also recognize than any combination of the various examples of processing-station arrangements of FIGS. 2C through 2H may be used as needed for a particular processing tool. The combinations may be used to minimize an overall footprint, combine a variety of processes into one tool, or for various other reasons as understood by the skilled artisan.

FIG. 2C shows a two-station configuration 240 of a multi-station module 241 having two processing stations 203. FIG. 2D shows a first three-station configuration 250 of a multi-station module 251 having three processing stations 203. FIG. 2E shows a second three-station configuration 260 of a multi-station module 261 having three processing stations 203. Upon reading and understanding the disclosed subject matter, a person of ordinary skill in the art will recognize that, for example, the first three-station configuration 250 and the second three-station configuration 260 may be arranged in close proximity to each other, thereby again reducing an overall footprint of a process tool using such processing station configurations.

FIG. 2F shows a five-station configuration 270 of a multi-station module 271 having five processing stations 203. FIG. 2G shows a six-station configuration 280 of a multi-station module 281 having six processing stations 203. FIG. 2H shows a seven-station configuration 290 of a multi-station module 291 having seven processing stations 203.

The various examples of processing-station arrangements within a processing module of FIGS. 2C through 2H are provided as examples only. The skilled artisan will recognize that various numbers and arrangements of the processing stations, in addition to those shown, may be considered and still be within a scope of the disclosed subject matter.

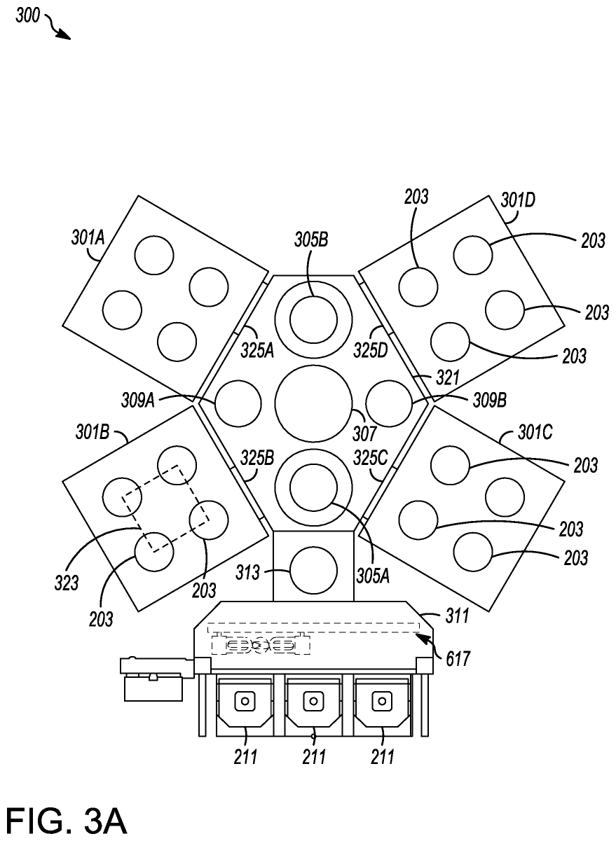

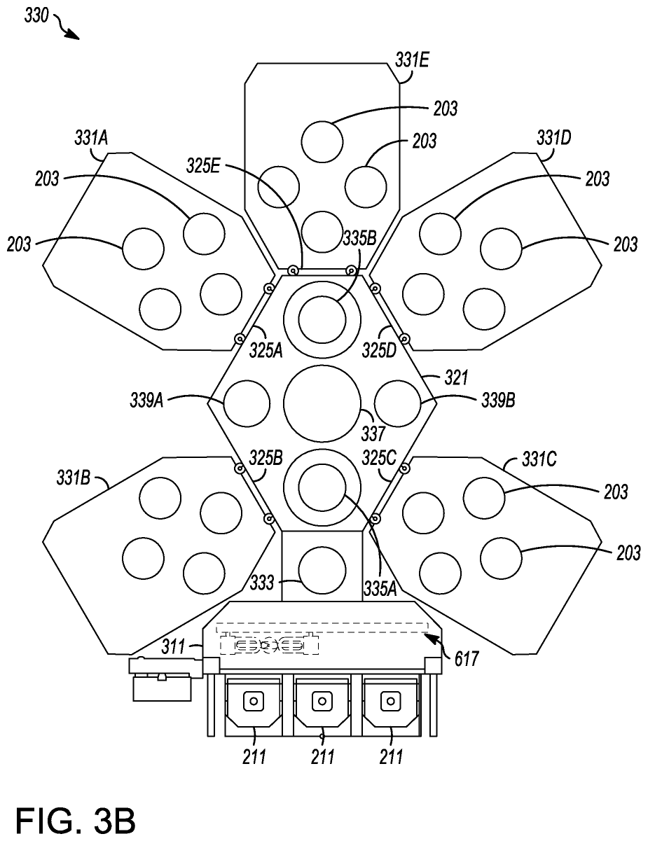

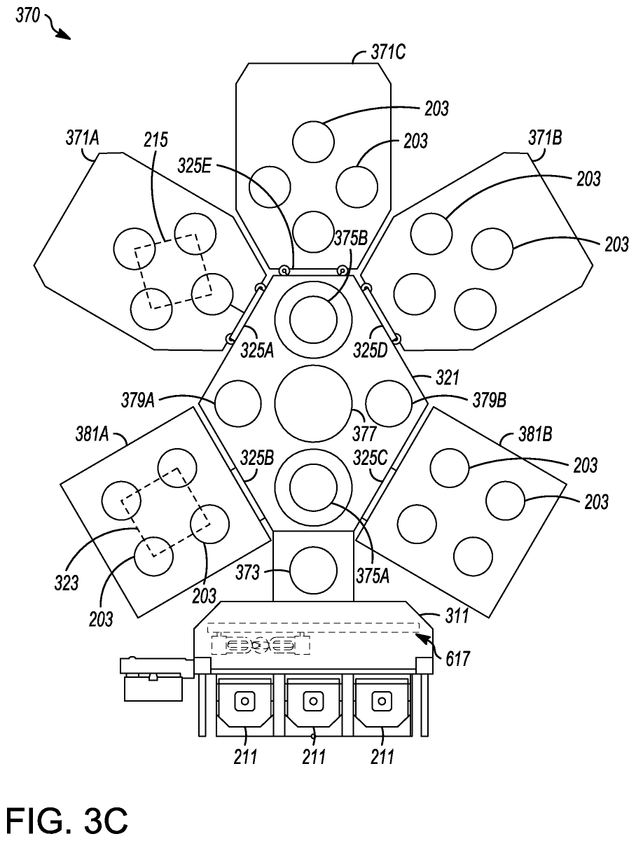

FIG. 3A shows an exemplary embodiment of a cut-away plan view of a multi-station, semiconductor-processing tool 300 having a square-shaped arrangement 323 of processing stations 203. The semiconductor-processing tool 300 is shown to include a plurality of multi-station modules 301A-301D. Although the plurality of the multi-station modules 301A-301D is shown with individual ones of the modules splayed at angles with reference to one another, no such angular limitation is intended. That is, the multi-station modules 301A-301D may be arranged such that at least one edge of one module is parallel to at least one other of the modules. As shown, a chamber transfer-port 325A-325D is located between a vacuum-transfer module 321 and each multi-station module 301A-301D.

The semiconductor-processing tool 300 is also shown to include additional processing-stations including a first processing-station 307, a second processing-station 309A, and a third processing-station 309B. The additional ones of the processing stations 307, 309A, 309B are each located within the vacuum-transfer module 321 and therefore can be subjected to high-vacuum environments (e.g., a few Torr or lower). Although three of the processing stations are shown, upon reading and understanding the disclosed subject matter, a person of ordinary skill in the art will recognize that more or fewer processing stations may be contained within the vacuum-transfer module 321. For example, in exemplary embodiments, there may be one, two, four, five, or more processing stations contained within the vacuum-transfer module 321. Three of the processing stations are shown simply as an example to illustrate additional aspects of the disclosed subject matter.

Similar or identical to the semiconductor-processing tool 200 of FIG. 2A, each of the substrates is loaded into the semiconductor-processing tool 300 by the linear ATR 617 located within a reduced-depth EFEM 311. The linear ATR 617 loads at least a single substrate at a time from one of a plurality of substrate carriers 211 onto the transfer station 313. The transfer station 313 may be the same as or similar to the transfer stations 213, 207, 233, 237 of FIGS. 2A and 2B.

The semiconductor-processing tool 300 is also shown to include a front vacuum-transfer robots (VTR) 305A, more proximate the transfer station 313, and a rear VTR 305B, located at the rear of the semiconductor-processing tool 300. The skilled artisan will appreciate that the front VTR 305A and the rear VTR 305B are depicted schematically as circles so as not to obscure other components of the disclosed subject matter. The front VTR 305A and the rear VTR 305B may be the same as or similar to the vacuum-transfer robots 205A, 205B, 235A, 235B of FIGS. 2A and 2B. The front VTR 305A may either transfer a substrate from the transfer station 313 to one of the processing stations 203. Alternatively, the front VTR 305A may transfer the substrate to one of the processing stations 307, 309A, 309B. In a similar fashion, the rear VTR 305B may either transfer a substrate from, for example, one of the processing stations 307, 309A, 309B to one of the processing stations 203. Alternatively, the front VTR 305A may transfer the substrate from one of the processing stations 203 to one of the processing stations 307, 309A, 309B. In another possible combination of transfers, the front VTR 305A may transfer the substrate from one of the processing stations 203 to another one of the processing stations 203.

In a specific exemplary embodiment, the first processing-station 307 comprises a pre-clean station. A pre-clean operation is often employed in semiconductor processing operations to remove, for example, native oxides (e.g., on silicon wafers) and other impurities from the surface (or surfaces) of a substrate.

In a specific exemplary embodiment, the second processing-station 309A and the third processing-station 309B each comprise a degas station. In an exemplary degas operation, after entering the high-vacuum environment of the vacuum-transfer module 321, the substrate may be subjected to a desorption step at the second processing-station 309A or the third processing-station 309B. The degas operation may be performed in an inert-gas environment (e.g., argon (Ar)) and may be performed at a temperature significantly higher (e.g., by about 50° C. to about 100° C.) than the other operations in a processing sequence. In general, the degas operation can remove gaseous and/or liquid substances, such as moisture and films on the substrate.

In operations such as pre-clean and degas operations, some level of vacuum (e.g., a few Torr or lower of pressure) is achieved by pumping down the vacuum-transfer module 321. Overall, including additional types of processing stations within the vacuum-transfer module 321 adds significant processing capabilities for processing of substrates and greatly improves substrate throughput.

In various embodiments, the additional processing-stations (e.g., the first processing-station 307, the second processing-station 309A, and the third processing-station 309B) can be configured to perform functions other than pre-clean or degas operations. In various embodiments, one or more of the additional processing-stations can be configured to perform post-processing operations as well. Post-processing operations can include, for example, rapid thermal-annealing and other processes known to a person of ordinary skill in the art. In various embodiments, one or more of the additional processing-stations can be configured alternately to perform pre- and post-processing operations.

FIG. 3B shows an exemplary embodiment of a cut-away plan view of a multi-station, semiconductor-processing tool 330 having a diamond-shaped arrangement of processing stations. The semiconductor-processing tool 300 includes additional processing-stations 337, 339A, 339B located within the vacuum-transfer module 321, in accordance with embodiments of the disclosed subject matter. The processing stations 337, 339A, 339B provide significant additional process capabilities, as described above with reference to FIG. 3A. As is also described with reference to FIG. 3A, although three of the additional processing-stations are shown, upon reading and understanding the disclosed subject matter, a person of ordinary skill in the art will recognize that more or fewer additional processing-stations may be contained within the vacuum-transfer module 321. For example, in exemplary embodiments, there may be one, two, four, five, or more processing stations contained within the vacuum-transfer module 321. Three of the processing stations are shown simply as an example to illustrate additional aspects of the disclosed subject matter. As described above with reference to FIG. 3A, and in a specific exemplary embodiment, the first processing-station 337 comprises a pre-clean station. The second processing-station 309A and the third processing-station 309B may each comprise a degas station. In other embodiments, at least one of the processing stations 307, 309A, 309B may comprise a post-processing station. In other embodiments, the processing stations 307, 309A, 309B may alternately comprise a pre-processing and a post-processing operation.

Further, as shown, a chamber transfer-port 325A-325E is located between the vacuum-transfer module 321 and each multi-station module 331A-331E. Similar or identical to the semiconductor-processing tool 300 of FIG. 3A, each of the substrates is loaded into the semiconductor-processing tool 330 by the linear ATR 617 located within a reduced-depth EFEM 311. The linear ATR 617 loads at least a single substrate at a time from one of a plurality of substrate carriers 211 onto the transfer station 333. In operations such as pre-clean and degas operations, some level of vacuum (e.g., a few Torr or lower of pressure) is achieved by pumping down the vacuum-transfer module 321.

The semiconductor-processing tool 330 is also shown to include a front vacuum-transfer robot (VTR) 335A and a rear VTR 335B. The skilled artisan will appreciate that the front VTR 335A and the rear VTR 335B are depicted schematically as circles so as not to obscure other components of the disclosed subject matter. The front VTR 335A and the rear VTR 335B may the same as or similar to the vacuum-transfer robots 305A, 305B of FIG. 3A.

The diamond-shaped arrangement 215 (see FIG. 2A) of the processing stations 203 within each of the multi-station module 331A-331E allows adjacent ones of the modules to be placed in closer proximity to one another than would be possible with the square-shaped arrangement 323 of FIG. 3A. With continuing reference to FIG. 3B, a person of ordinary skill in the art will recognize that, based on the diamond-shaped arrangement of the processing stations 203, adjacent ones of the modules, such as the multi-station modules 331A, 331E, 331D located at a portion of the semiconductor-processing tool 330 most distal from the reduced-depth EFEM 311 (most distal meaning at the rear of the tool; as shown near the top of the page) may be placed in closer proximity to one another than the quad-station modules 101A-101D of FIG. 1. That is, the diamond-shaped arrangement allows a portion of the modules to have an angled outer-surface 227 (see FIG. 2A). The angled outer-surface 227 allows the modules to have an increase packing density—the multi-station modules 331A-331E may be placed together in a smaller footprint while still including the same number of the processing stations 203 in each module.

FIG. 3C shows an exemplary embodiment of a cut-away plan view of a multi-station, semiconductor-processing tool 370 having both the square-shaped arrangement 323 and the diamond-shaped arrangement 215 of processing stations 203. Due to the square-shaped arrangements 323 and diamond-shaped arrangements 215 of the processing stations 203, the semiconductor-processing tool 370 may be considered to have a hybrid-arrangement of processing stations.

The semiconductor-processing tool 370 is shown to include additional processing-stations 377, 379A, 379B located within the vacuum-transfer module 321, in accordance with embodiments of the disclosed subject matter. The additional processing-stations 377, 379A, 379B provide significant additional process capabilities, as described above with reference to FIG. 3A. As is also described with reference to FIG. 3A, although three of the additional processing-stations are shown, upon reading and understanding the disclosed subject matter, a person of ordinary skill in the art will recognize that more or fewer additional processing-stations may be contained within the vacuum-transfer module 321. For example, in exemplary embodiments, there may be one, two, four, five, or more processing stations contained within the vacuum-transfer module 321. Three of the processing stations are shown simply as an example to illustrate additional aspects of the disclosed subject matter. As described above with reference to FIG. 3A, and in a specific exemplary embodiment, the first processing-station 377 comprises a pre-clean station. The second processing-station 379A and the third processing-station 379B may each comprise a degas station. One or more of the additional processing-stations 377, 379A, 379B may also be arranged to perform post-processing operations or alternately perform pre- and post-processing operations.

Further, as shown, a chamber transfer-port 325A-325E is located between the vacuum-transfer module 321 and each multi-station module 371A-371E. Similar or identical to the semiconductor-processing tool 300 of FIG. 3A, each of the substrates is loaded into the semiconductor-processing tool 370 by the linear ATR 617 located within a reduced-depth EFEM 311. The linear ATR 617 loads at least a single substrate at a time from one of a plurality of substrate carriers 211 onto the transfer station 373. In operations such as pre-clean and degas operations, some level of vacuum (e.g., a few Torr or lower of pressure) is achieved by pumping down the vacuum-transfer module 321.

The semiconductor-processing tool 370 is also shown to include a front vacuum-transfer robot (VTR) 375A and a rear VTR 375B. The skilled artisan will appreciate that the front VTR 375A and the rear VTR 375B are depicted schematically as circles so as not to obscure other components of the disclosed subject matter. The front VTR 375A and the rear VTR 375B may the same as or similar to the vacuum-transfer robots 305A, 305B of FIG. 3A.

The diamond-shaped arrangement 215 of the processing stations 203 within each of the multi-station module 371A, 371B, 371C allows adjacent ones of the modules to be placed in closer proximity to one another than would be possible with the square-shaped arrangement 323 of FIG. 3A. With continuing reference to FIG. 3C, a person of ordinary skill in the art will recognize that, based on the diamond-shaped arrangement 215 of the processing stations 203, adjacent ones of the modules, such as the multi-station modules 371A, 371B, 371C located at a portion of the semiconductor-processing tool 370 most distal from the reduced-depth EFEM 311 (most distal meaning at the rear of the tool or near the top of the page) may be placed in closer proximity to one another than multi-station modules 381A, 381B. That is, the diamond-shaped arrangement 215 allows a portion of the modules to have an angled outer-surface 227 (see FIG. 2A). The angled outer-surface 227 allows the modules to have an increased packing-density—the multi-station modules 371A-371C may be placed together in a smaller footprint while still including the same number of the processing stations 203 in each module.

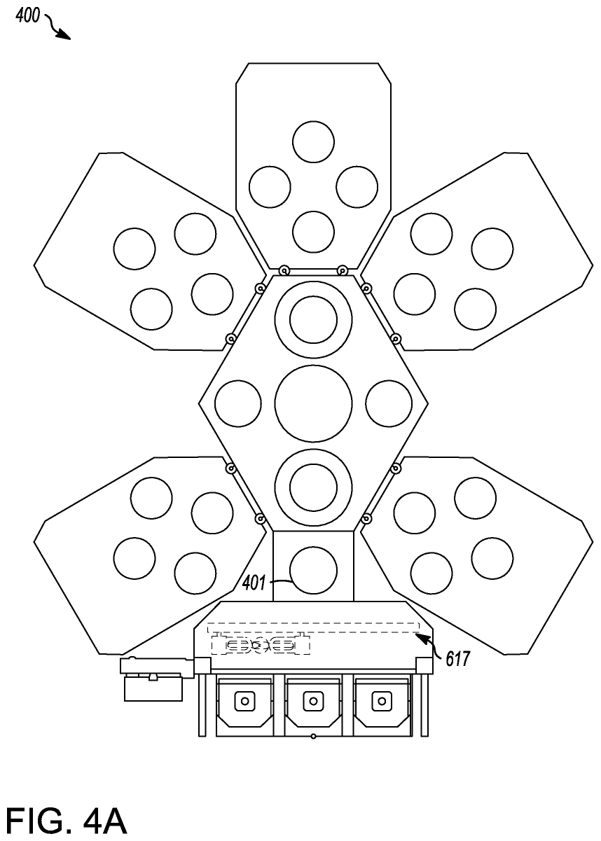

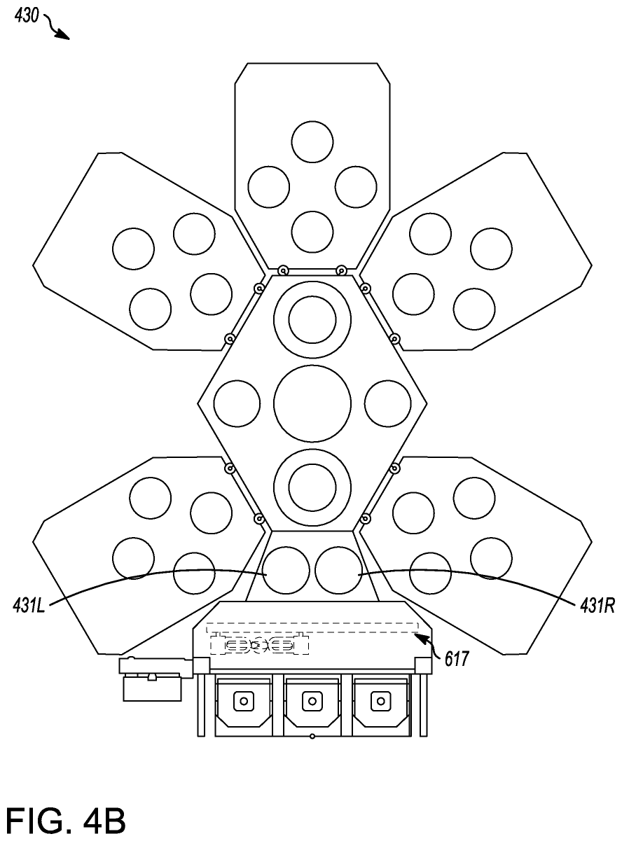

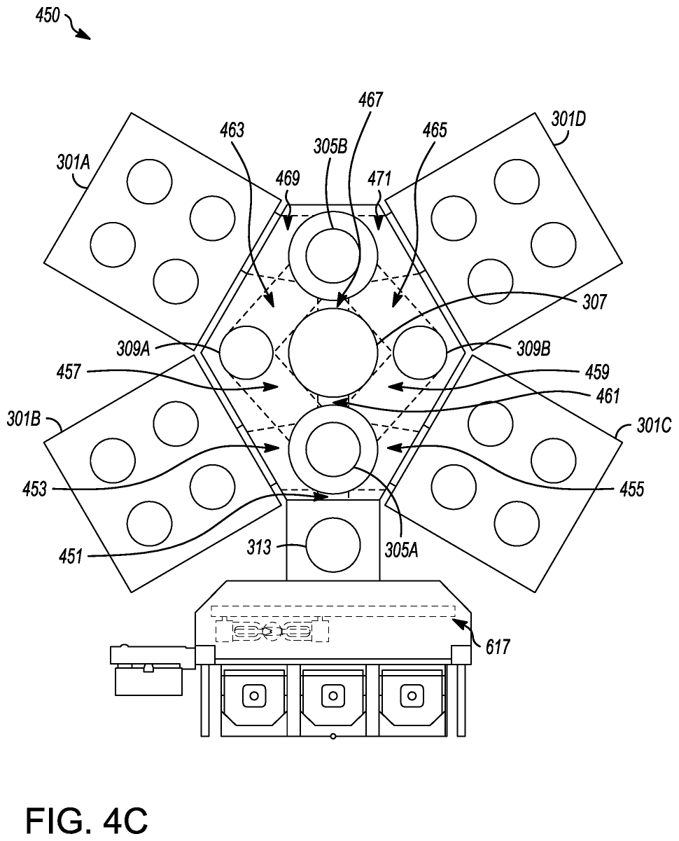

With reference now to FIG. 4A, a semiconductor-processing tool 400 is shown that includes a dual-level load-lock and transfer station 401 (or substrate-transfer port). The semiconductor-processing tool 400 is in accordance with various embodiments of the disclosed subject matter as described above with reference to FIGS. 2A through 3C. A person of ordinary skill in the art will understand that one of the transfer stations is located above the other. Consequently, the dual-level load-lock and transfer station 401 has a first level load-lock located in a first x-y plane and the second dual-level load-lock and transfer station located in a second x-y plane that is either higher or lower than the first x-y plane. Therefore, one of the transfer stations is not shown explicitly in the plan view of FIG. 4A. The semiconductor-processing tool 400 may otherwise be the same as, for example, the semiconductor-processing tool 330 of FIG. 3B. However, the dual-level load-lock and transfer station 401 may be used with any of the semiconductor-processing tools of the disclosed subject matter shown and described herein. Overall, a skilled artisan will recognize that the dual-level load-lock and transfer station 401 can increase substrate throughput significantly.

FIG. 4B shows an exemplary embodiment of a semiconductor-processing tool 430 includes a tandem, dual-level load-lock and transfer station. The tandem, dual-level load-lock and transfer station includes a left-side pair (one above the other) of transfer stations 431L and a right-side pair (one above the other) of transfer stations 431R (or substrate-transfer ports). The semiconductor-processing tool 430 is in accordance with embodiments of the disclosed subject matter as described above with reference to FIGS. 2A through 3C. A person of ordinary skill in the art will understand that, since one of the transfer stations is located above the other, each of the pair of transfer stations is therefore not shown explicitly in the plan view of FIG. 4B. Consequently, the dual-level load-lock and transfer stations 431L and 431R each have a first level load-lock located in a first x-y plane and the second dual-level load-lock and transfer station located in a second x-y plane that is either higher or lower than the first x-y plane. The semiconductor-processing tool 430 may otherwise be the same as, for example, the semiconductor-processing tool 330 of FIG. 3B. However, the tandem, dual-level load-lock and transfer stations 431L, 431R may be used with any of the semiconductor-processing tools of the disclosed subject matter shown and described herein. Overall, a skilled artisan will recognize that the tandem, dual-level load-lock and transfer station 431L, 431R can increase substrate throughput significantly. The skilled artisan will further recognize that more than two dual-level load-lock and transfer stations can be used side-by-side or one above another.

FIG. 4C shows an exemplary embodiment of a semiconductor-processing tool 450 indicating substrate transfer-paths on different levels, which is in accordance with embodiments of the disclosed subject matter. The semiconductor-processing tool 450 of FIG. 4C can be considered in light of the semiconductor-processing tool 430 of FIG. 4B. In FIG. 4B, the dual-level load-lock and transfer stations 431L and 431R each have a first level load-lock located in a first x-y plane and the second dual-level load-lock and transfer station located in a second x-y plane that is either higher or lower than the first x-y plane. In FIG. 4C, with reference to the description below, various substrate transfer paths may be considered to be located in a first x-y plane that is either higher or lower than a second x-y plane. Accordingly, the various associated vacuum-transfer robots, and processing stations located within the vacuum-transfer module, may also be considered to be in either the first x-y plane or the second x-y plane. Therefore, the various vacuum-transfer robots, and processing stations located within the vacuum-transfer module will be referred to the description of FIG. 4C, below, as being at a level substantially within the same x-y plane as the substrate transfer-paths

For example, in a specific exemplary embodiment, substrates may be transferred from the linear ATR 617 to lower-level version of the transfer station 313 (not shown explicitly) via a first transport-path 451. The substrate may then be transferred from the lower-level version of the transfer station 313 by a lower-level version of the front VTR 305A to either: (1) one of the lower-level processing stations of the multi-station module 301B, via a second transport-path 453; (2) one of the lower-level processing stations of the multi-station module 301C, via a third transport-path 455; (3) a lower-level implementation of the first processing-station 307, via a fourth transport-path 461; (4) a lower-level implementation of the second processing-station 309A, via a fifth transport-path 457; or (5) a lower-level implementation of the third processing-station 309B, via a sixth transport-path 459.

In a similar fashion, the substrate may then be transferred from the lower-level version of the first processing station 307 by a lower-level version of the rear VTR 305B to either: (1) one of the lower-level processing stations of the multi-station module 301A, via a seventh transport-path 467 and an eighth transport-path 469; (2) one of the lower-level processing stations of the multi-station module 301D, via the seventh transport-path 467 and a ninth transport-path 471; (3) a lower-level implementation of the second processing-station 309A, via a tenth transport-path 463; or (4) a lower-level implementation of the third processing-station 309B, via an eleventh transport-path 465.

Upon reading and understanding the disclosed subject matter, a person of ordinary skill in the art will recognize that each of the transport-paths may be used in other combinations as well that are not detailed explicitly herein. The skilled artisan will also recognize that the multi-level configuration of FIG. 4C to also be extended to more than two levels. For example, the multi-level configuration may be extended to three, four, or more levels and still be considered within a scope of the disclosed subject matter.

In various embodiments, each of the lower-level implementations of the first processing station 390, the second processing-station 309A, and the third processing-station 309B may be the same as or similar to the first processing station 390, the second processing-station 309A, and the third processing-station 309B of FIG. 3A. In various embodiments, each of the lower-level implementations of the first processing station 390, the second processing-station 309A, and the third processing-station 309B may be dissimilar to, or arranged inter alia, alternative configuration that the first processing station 390, the second processing-station 309A, and the third processing-station 309B of FIG. 3A.

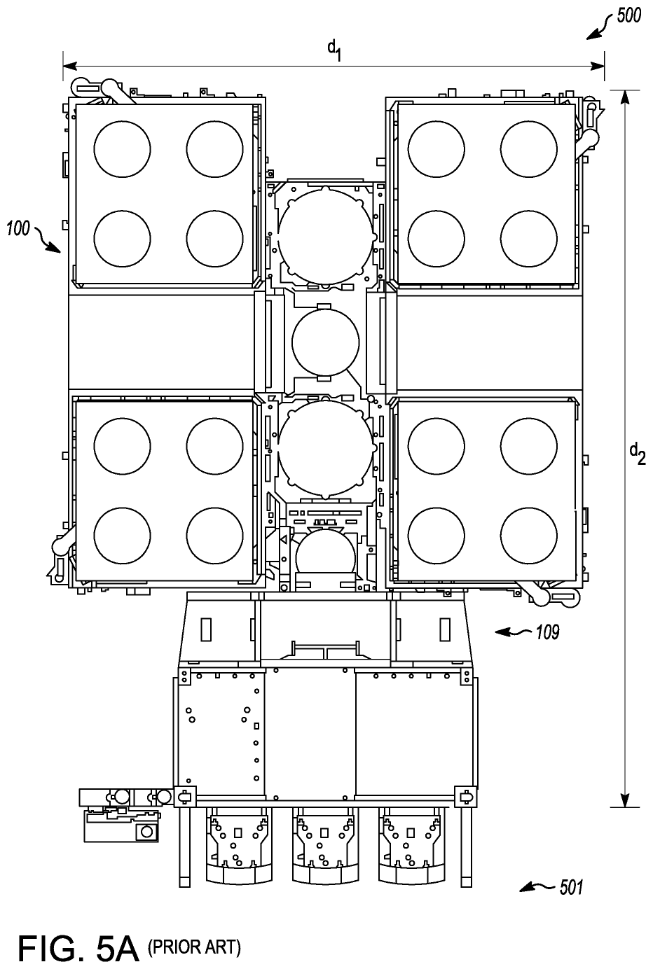

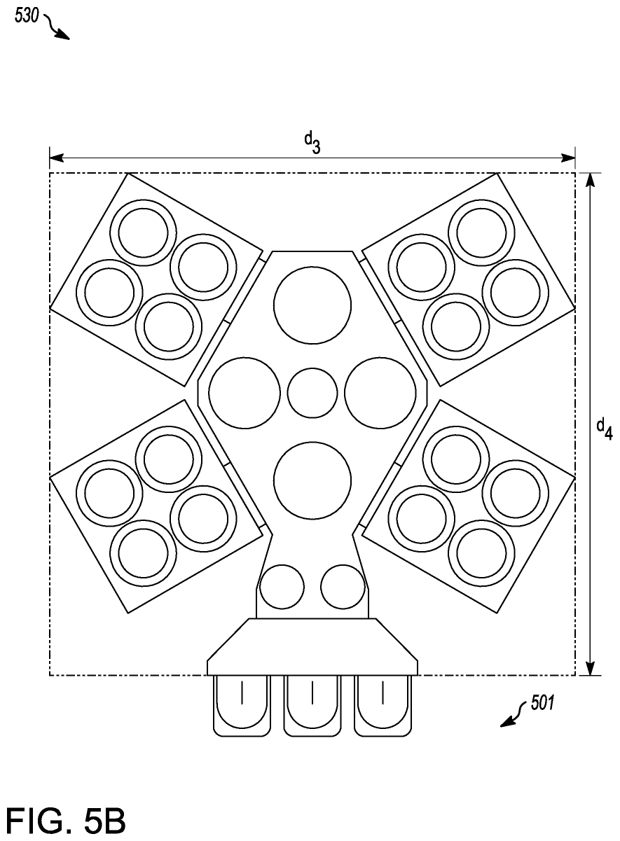

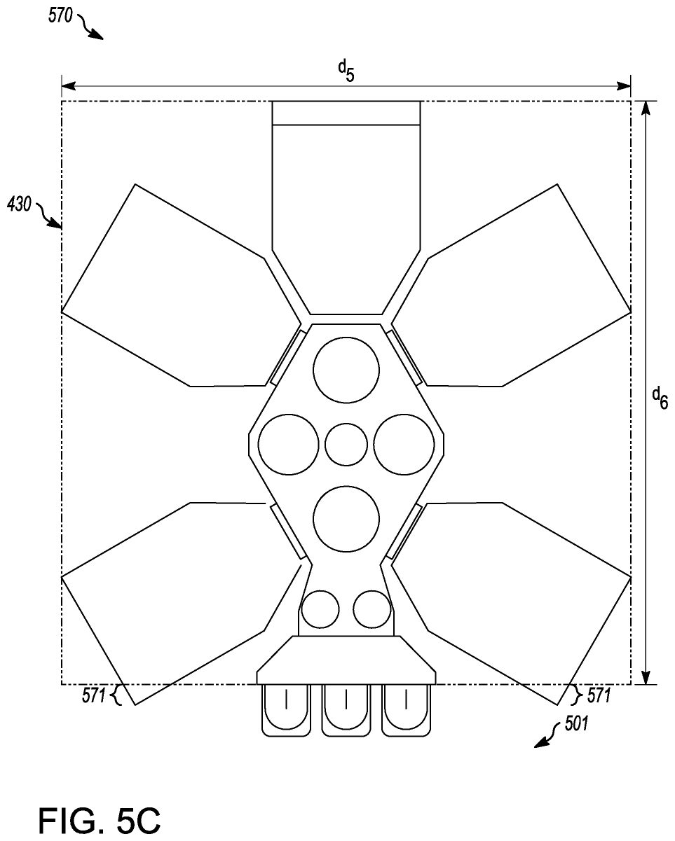

FIG. 5A shows an example of dimensions 500 comprising a typical footprint of the semiconductor-processing tool 100 of FIG. 1. Most or all of the semiconductor-processing tool is located within an equipment chase. Primarily only the substrate carriers are located within a fabrication environment 501 (e.g., a cleanroom in which process engineers interface with the tools). Example ratios of dimensions are shown in Table I, below.

TABLE I

| | |
|---|---|
| Width [d₁] | x |
| Depth [d₂] | 1.3x |
| Number of Processing | 16 |
| Stations [Number] | |
| Density of Processing | 1.1 |
| Stations [Number/Unit Area] | |
| Number of Additional | 0 |
| Processing Stations [Number] | |
| Density of Processing | 1.1 |
| Stations Including Additional | |
| Processing Stations | |
| [Number/Unit Area] | |
| Notes | Overall depth penalized by |
| | bump-out region 109 |

FIGS. 5B and 5C show examples of dimension ratios comprising a footprint of the tool arrangements discussed in accordance with various embodiments of the disclosed subject matter as provided in certain examples of FIG. 2A through FIG. 4B. The dimension ratios are provided with reference to the ratios of dimensions are shown in Table I, of the prior art. For example, with reference to the dimensions 530 of FIG. 5B, example ratios of dimensions are shown in Table II, below. However, a person of ordinary skill in the art will readily understand that these are examples only. Therefore, these example ratios are provided merely as an aid in understanding the increased density of processing stations possible by incorporating at least certain aspects of the disclosed subject matter.

TABLE II

| | |
|---|---|
| Width [d₃] | 1.2x |
| Depth [d₄] | 1.1x |
| Number of Processing | 16 |
| Stations [Number] | |
| Density of Processing | 1.2 |
| Stations [Number/Unit | |
| Area] | |
| Number of Additional | 3 |
| Processing Stations | |
| [Number] | |
| Density of Processing | 1.4 |
| Stations Including | |
| Additional Processing | |
| Stations [Number/Unit | |
| Area] | |
| Notes | Includes additional and integral |
| | pre- or post-processing/treatment |
| | stations plus at least one |
| | additional load-lock and transfer |
| | station/substrate-transfer port |

With reference to the dimensions 570 of FIG. 5C, showing the semiconductor-processing tool 430 Of FIG. 4B as an example, the dimension ratios are shown in Table III, below, in comparison with the ratios of dimensions are shown in Table I of the prior art. Again, the person of ordinary skill in the art will readily understand that these are examples only. Therefore, these example ratios are provided merely as an aid in understanding the increased density of processing stations possible by incorporating at least certain aspects of the disclosed subject matter.

In this example, the semiconductor-processing tool 430 is located within an equipment chase. Primarily only the substrate carriers are located within a fabrication environment 501 except for a portion 571 of the modules that can be located with the fabrication environment 501.

TABLE III

| | |
|---|---|
| Width [d₅] | 1.5x |
| Depth [d₆] | 1.1x |
| Number of Processing | 20 |
| Stations [Number] | |
| Density of Processing | 0.9 |
| Stations [Number/Unit | |
| Area] | |
| Number of Additional | 3 |
| Processing Stations | |
| [Number] | |
| Density of Processing | 1.0 |
| Stations Including | |
| Additional Processing | |
| Stations [Number/Unit | |
| Area] | |
| Notes | Includes additional and integral |
| | pre- or post-processing/treatment |
| | stations plus at least one |
| | additional load-lock and transfer |
| | station/substrate-transfer port |

With concurrent reference to FIGS. 5A through 5C, upon reading and understanding the disclosed subject matter, a person of ordinary skill in the art will recognize that various tool configurations using the diamond-shaped arrangement can increase the density of processing stations in various embodiments. In other embodiments, the additional processing-stations (e.g., the pre-clean and degas stations within the vacuum-transfer module) can add significant processing capabilities for processing of substrates and greatly improve substrate throughput. In other embodiments, a combination of the diamond-shaped arrangement and the additional processing-stations can increase the density of processing stations and/or add significant processing capabilities by incorporating the additional processing-stations.

FIGS. 6A and 6B show exemplary plan view and elevational views, respectively, of the atmospheric transfer-robot (ATR) 617 that is compatible with a reduced-depth equipment front-end module (EFEM) 600, which may be used with various embodiments of the disclosed subject matter.

With reference to the exemplary plan view 601A of FIG. 6A and the elevational view 601B of FIG. 6B, the linear ATR 617 may be mounted to one or more vertical rails 603 within the EFEM 600. The one or more vertical rails 603 are in turn mounted on a horizontal rail 601. The linear ATR 617 is configured to raise and lower in a vertical, Z-direction on the vertical rails 603. For example, the linear ATR 617 may be mounted in slots (not shown explicitly but understandable to a person of ordinary skill in the art) in the vertical rails 603. Conversely, the linear ATR 617 is configured to slide in a horizontal, X-direction on the vertical rails 603 along the horizontal rail 601. Consequently, a position of the linear ATR 617 may be adjusted in the Z-direction and the X-direction to provide access to multiple load-locks 615 and loading stations containing the substrate carriers 211 (see FIG. 2A, not shown explicitly if FIG. 6A or 6B). Both the loading stations and the multiple load-locks 615 may be at different heights (at different levels in in the Z-direction).

In one example, the linear ATR 617 includes two arms 613. In FIG. 6A, one of the two arms 613 overlaps the other (a folded configuration of the two arms 613). Each of the two arms 613 includes an arm segment 605 and an end effector 607. In various embodiments, one of the two arms 613 may be longer than the other. Also, although two arms are shown, a skilled artisan, upon reading and understanding the disclosed subject matter, will recognize that a single arm or more than two arms may be used in various configurations. In various embodiments, one of the two arms 613 may be longer than the other, depending on, for example, an overall arrangement of the EFEM 600 in relationship to various ones of the substrate carriers 211 (e.g., see FIG. 2A) and the multiple load-locks 615.

When the two arms 613 are in a folded configuration as shown, the linear ATR 617 has a relatively narrow profile (e.g., in comparison with dimensions of the substrate being transported) relative to the EFEM 600. Accordingly, the EFEM 600 is configured to accommodate at least a portion of the multiple load-locks 615 and respective ones of vacuum gates (not show explicitly).

In various embodiments, the EFEM 600 may include an integrated substrate aligner 609. In this example, having one of the two arms 613 have a greater overall length than the other allows respective ones of the end effectors 607 to be positioned over the integrated substrate aligner 609 when the linear ATR 617 is in the folded configuration shown in FIG. 6A. For example, the relative lengths of the arm segments 605 and the end effectors 607 allow a relatively-linear folded configuration in which the arm segments 605, the end effectors 607, and the integrated substrate aligner 609 are arranged on a line 611 (i.e., coaxial with the line 611).

With continuing reference to FIG. 6A and FIG. 6B, each of the two arms 613 may be mounted in the slot of a respective one of the vertical rails 603. For example, the vertical rails 603 may move independently of one another. In other words, although shown in a compact arrangement in FIGS. 6A and 6B (i.e., the vertical rails 603 are relatively close together), one of the vertical rails 603 may be moved to an end of the EFEM 600 opposite to the other one of the vertical rails 603. In this manner, respective ones of the two arms 613 are configured to access different ones of the loading stations and/or the multiple load-locks 615 at substantially the same time. In other examples, the EFEM 600 may include only one of the vertical rails 603 and a respective one of the two arms 613.

In some examples, and although not shown explicitly, additional space within the EFEM 600 achieved by the configuration of the linear ATR 617 may allow additional substrate processing and transfer system components to be located within the EFEM 600. For example, components including, but not limited to, metrology stations, storage buffers, notch-alignment stations, edge-ring storage, etc. may be located in the EFEM 600. In one example, when the two arms 613 are in the folded configuration, the linear ATR 617 occupies less than, for example, 50% of an overall depth of the EFEM 600.

As used herein, the term “or” may be construed in an inclusive or exclusive sense. Further, other embodiments will be understood by a person of ordinary skill in the art based upon reading and understanding the disclosure provided. Moreover, the person of ordinary skill in the art will readily understand that various combinations of the techniques and examples provided herein may all be applied in various combinations.

Throughout this specification, plural instances may implement components, operations, or structures described as a single instance. Although individual operations are illustrated and described as separate operations, one or more of the individual operations may be performed concurrently, and, unless otherwise stated, nothing requires that the operations necessarily be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter described herein.

Further, although not shown explicitly but understandable to a skilled artisan, each of the vacuum-transfer robots described in FIG. 2A through FIG. 4B include multi-level transfer capabilities. Consequently, the VTRs each can include an extended z-range of motion. Accordingly, each of the transfer stations, load-lock chambers, processing stations, and related components can be of a multi-level design as well. Further, although not shown explicitly but recognizable to a person of ordinary skill in the art upon reading and understanding the disclosed subject matter, each of the vacuum-transfer modules described above may have only a single VTR. In other embodiments, three or more VTRs may be used in each vacuum-transfer-module. Therefore, each of the exemplary embodiments described above may contain one or more VTRs in each vacuum-transfer module. Moreover, each of the exemplary embodiments shown and described herein is merely representative of one possible configuration and should not be taken as limiting the scope of the disclosure.

Each of the vacuum-transfer robots of the disclosed subject matter can be any suitable robot capable of moving a substrate during processing. In some embodiments, the vacuum-transfer robots may have multiple arms. Each of the multiple arms can be moved independently of other ones of the arms. Each of the multiple arms can be moved independently in the x-y plane and/or along the z-axis (thereby covering multiple x-y planes).

Additionally, although four sides or six sides of the vacuum-transfer modules are shown, one skilled in the art will understand that there can be any suitable number of sides to the vacuum-transfer modules depending on, for example, an overall configuration of the semiconductor-processing tool.

Also, each of the substrate carriers may hold a number of substrates, which are processed and returned to the substrate carrier. Alternatively, one of the substrate carriers may hold unprocessed substrates which are moved to the another one of the substrate carriers after processing.

In various embodiments, the additional processing-stations (e.g., the first processing-station 307, the second processing-station 309A, and the third processing-station 309B) can be configured to perform functions other than pre-clean or degas operations. In various embodiments, one or more of the additional processing-stations can be configured to perform post-processing operations as well. In various embodiments, one or more of the additional processing-stations can be configured alternately to perform pre- and post-processing operations.

Although various embodiments are discussed separately, these separate embodiments are not intended to be considered as independent techniques or designs. As indicated above, each of the various portions may be inter-related and each may be used separately or in combination with other embodiments of the disclosed subject matter discussed herein. For example, although various embodiments of operations, systems, and processes have been described, these methods, operations, systems, and processes may be used either separately or in various combinations.

Consequently, many modifications and variations can be made, as will be apparent to a person of ordinary skill in the art upon reading and understanding the disclosure provided herein. Functionally equivalent methods and devices within the scope of the disclosure, in addition to those enumerated herein, will be apparent to the skilled artisan from the foregoing descriptions. Portions and features of some embodiments may be included in, or substituted for, those of others. Such modifications and variations are intended to fall within a scope of the appended claims. Therefore, the present disclosure is to be limited only by the terms of the appended claims, along with the full scope of equivalents to which such claims are entitled. It is also to be understood that the terminology used herein is for the purpose of describing particular embodiments only and is not intended to be limiting.

The Abstract of the Disclosure is provided to allow the reader to ascertain quickly the nature of the technical disclosure. The abstract is submitted with the understanding that it will not be used to interpret or limit the claims. In addition, in the foregoing Detailed Description, it may be seen that various features may be grouped together in a single embodiment for the purpose of streamlining the disclosure. This method of disclosure is not to be interpreted as limiting the claims. Thus, the following claims are hereby incorporated into the Detailed Description, with each claim standing on its own as a separate embodiment.

### THE FOLLOWING NUMBERED EXAMPLES ARE SPECIFIC EXEMPLARY EMBODIMENTS OF THE DISCLOSED SUBJECT MATTER

Example 1: An embodiment of the disclosed subject matter describes a semiconductor-processing tool that includes a plurality of multi-station modules and a plurality of processing stations. At least some of the plurality of processing stations are organized in a diamond-shaped arrangement in at least some of the plurality of multi-station modules. A vacuum-transfer module is coupled to each of the multi-station modules. The vacuum-transfer module has one or more vacuum-transfer robots to transfer substrates to and from at least one of the plurality of processing stations. At least one additional processing-station is located in the vacuum-transfer module.

Example 2: The semiconductor-processing tool of Example 1, wherein a remaining portion of the plurality of processing station are organized in a square-shaped arrangement in a remaining portion of the plurality of multi-station modules not containing the processing stations organized in the diamond-shaped arrangement.

Example 3. The semiconductor-processing tool of either of Example 1 or Example 2, further comprising at least one maintenance-aperture feature located between at least some adjacent ones of the plurality of multi-station modules.

Example 4. The semiconductor-processing tool of any one of the preceding Examples, further comprising at least one additional processing-station located in the vacuum-transfer module at a different level than the at least one additional processing-station.

Example 5. The semiconductor-processing tool of Example 4, wherein the at least one additional processing-station is accessible by either of the one or more vacuum-transfer robots within the vacuum-transfer module.

Example 6. The semiconductor-processing tool of Example 4, wherein the at least one additional processing-station comprises a pre-clean station.

Example 7. The semiconductor-processing tool of Example 4, wherein the at least one additional processing-station comprises a degas station.

Example 8. The semiconductor-processing tool of Example 4, wherein the at least one additional processing-station comprises a post-processing station.

Example 9. The semiconductor-processing tool of Example 4, wherein the at least one additional processing-station comprises a station configured to alternate between a pre-clean station and a post-processing station.

Example 9. The semiconductor-processing tool of Example 4, wherein the at least one additional processing-station comprises three stations.

Example 10. The semiconductor-processing tool of Example 9, wherein the three stations comprise at least one pre-clean station and at least one degas station.

Example 11. The semiconductor-processing tool of any one of the preceding Examples, further comprising a dual-level load-lock and transfer station having a first level load-lock located in a first x-y plane and a second dual-level load-lock and transfer station located in a second x-y plane, the second x-y plane being either higher or lower than the first x-y plane.

Example 12. The semiconductor-processing tool of any one of the preceding Examples, further comprising a tandem, dual-level load-lock and transfer station including a left-side pair of transfer stations and a right-side pair of transfer stations. The left-side pair of transfer stations and the right-side pair of transfer stations each having a first level load-lock located in a first x-y plane and a second dual-level load-lock and transfer station located in a second x-y plane. The second x-y plane is either higher or lower than the first x-y plane.

Example 13. An embodiment of the disclosed subject matter describes a semiconductor-processing tool that includes a plurality of multi-station modules and a plurality of processing stations located within each of the plurality of multi-station modules. A vacuum-transfer module is coupled to each of the multi-station modules. The vacuum-transfer module has one or more vacuum-transfer robots to transfer substrates to and from at least one of the plurality of processing stations. At least one additional processing-station is located in the vacuum-transfer module.

Example 14. The semiconductor-processing tool of Example 13, wherein the at least one additional processing-station is accessible by either of the one or more vacuum-transfer robots within the vacuum-transfer module.

Example 15. The semiconductor-processing tool of either one of Example 13 or Example 14, wherein the at least one additional processing-station comprises a pre-clean station.

Example 16. The semiconductor-processing tool of any one of Examples 13 through 15, wherein the at least one additional processing-station comprises a degas station.

Example 17. The semiconductor-processing tool of any one of Examples 13 through 16, wherein the at least one additional processing-station comprises a post-processing station.

Example 18. The semiconductor-processing tool of any one of Examples 13 through 17, wherein the at least one additional processing-station comprises a station configured to alternate between a pre-clean station and a post-processing station.

Example 19. The semiconductor-processing tool of any one of Examples 13 through 18, wherein the at least one additional processing-station comprises three stations.

Example 20. The semiconductor-processing tool of Example 19, wherein the three stations comprise at least one pre-clean station and at least one degas station.

Example 21. The semiconductor-processing tool of Example 19, wherein at least some of the plurality of processing stations are organized in a diamond-shaped arrangement in at least some of the plurality of multi-station modules.

Example 22. An embodiment of the disclosed subject matter describes a semiconductor-processing tool that includes a plurality of multi-station modules and a hybrid-arrangement of a plurality of processing stations. At least some of the hybrid-arrangement of the plurality of processing stations are organized in a diamond-shaped arrangement in at least some of the plurality of multi-station modules. A remaining portion of the hybrid-arrangement of the plurality of processing stations is organized in a square-shaped arrangement in a remaining portion of the plurality of the plurality of multi-station modules not containing the processing stations organized in the diamond-shaped arrangement. A vacuum-transfer module is coupled to each of the multi-station modules. The vacuum-transfer module has one or more vacuum-transfer robots to transfer substrates to and from at least one of the plurality of processing stations. A plurality of additional processing-stations is located in the vacuum-transfer module.

Example 23. The semiconductor-processing tool of Example 22, further comprising at least one additional processing-station located in the vacuum-transfer module.

Example 24. The semiconductor-processing tool of either one of Example 22 or Example 23, further comprising a linear atmospheric transfer-robot located in an equipment front-end module (EFEM) of the semiconductor-processing tool.

Example 25. The semiconductor-processing tool of any one of Examples 22 through 24, further comprising at least one maintenance-aperture feature located between at least some adjacent ones of the plurality of multi-station modules.

Example 26. The semiconductor-processing tool of any one of Examples 22 through 25, further comprising at least one additional processing-station located in the vacuum-transfer module at a different level than the at least one additional processing-station.

Example 27. The semiconductor-processing tool of Example 26, wherein the at least one additional processing-station is accessible by either of the one or more vacuum-transfer robots within the vacuum-transfer module.

Example 28. The semiconductor-processing tool of Example 26, wherein the at least one additional processing-station comprises a pre-clean station.

Example 29. The semiconductor-processing tool of Example 26, wherein the at least one additional processing-station comprises a degas station.

Example 30. The semiconductor-processing tool of Example 26, wherein the at least one additional processing-station comprises a post-processing station.

Example 31. The semiconductor-processing tool of Example 26, wherein the at least one additional processing-station comprises a station configured to alternate between a pre-clean station and a post-processing station.

Example 32. The semiconductor-processing tool of Example 26, wherein the at least one additional processing-station comprises three stations.

Example 33. The semiconductor-processing tool of Example 32, wherein the three stations comprise at least one pre-clean station and at least one degas station.

Example 34. The semiconductor-processing tool of any one of Examples 22 through 33, further comprising a dual-level load-lock and transfer station having a first level load-lock located in a first x-y plane and a second dual-level load-lock and transfer station located in a second x-y plane. The second x-y plane is either higher or lower than the first x-y plane.

Example 35. The semiconductor-processing tool of any one of Examples 22 through 34, further comprising a tandem, dual-level load-lock and transfer station including a left-side pair of transfer stations and a right-side pair of transfer stations. The left-side pair of transfer stations and the right-side pair of transfer stations each have a first level load-lock located in a first x-y plane and a second dual-level load-lock and transfer station located in a second x-y plane. The second x-y plane is either higher or lower than the first x-y plane.

What is claimed is:

1. A semiconductor-processing tool, comprising:
a plurality of multi-station modules;
a plurality of processing stations, at least some of the plurality of processing stations organized in a diamond-shaped arrangement in at least some of the plurality of multi-station modules;
a vacuum-transfer module coupled to each of the multi-station modules, the vacuum-transfer module having one or more vacuum-transfer robots to transfer substrates to and from at least one of the plurality of processing stations; and
at least one additional processing-station located in the vacuum-transfer module.

2. The semiconductor-processing tool of claim 1, wherein a remaining portion of the plurality of processing station are organized in a square-shaped arrangement in a remaining portion of the plurality of multi-station modules not containing the processing stations organized in the diamond-shaped arrangement.

3. The semiconductor-processing tool of claim 1, further comprising at least one maintenance-aperture feature located between at least some adjacent ones of the plurality of multi-station modules.

4. The semiconductor-processing tool of claim 1, further comprising at least one additional processing-station located in the vacuum-transfer module at a different level than the at least one additional processing-station.

5. The semiconductor-processing tool of claim 4, wherein the at least one additional processing-station is accessible by either of the one or more vacuum-transfer robots within the vacuum-transfer module.

6. The semiconductor-processing tool of claim 4, wherein the at least one additional processing-station comprises a pre-clean station.

7. The semiconductor-processing tool of claim 4, wherein the at least one additional processing-station comprises a degas station.

8. The semiconductor-processing tool of claim 4, wherein the at least one additional processing-station comprises a post-processing station.

9. The semiconductor-processing tool of claim 4, wherein the at least one additional processing-station comprises a station configured to alternate between a pre-clean station and a post-processing station.

10. The semiconductor-processing tool of claim 4, wherein the at least one additional processing-station comprises three stations.

11. The semiconductor-processing tool of claim 10, wherein the three stations comprise at least one pre-clean station and at least one degas station.

12. The semiconductor-processing tool of claim 1, further comprising a dual-level load-lock and transfer station having a first level load-lock located in a first x-y plane and a second dual-level load-lock and transfer station located in a second x-y plane, the second x-y plane being either higher or lower than the first x-y plane.

13. The semiconductor-processing tool of claim 1, further comprising a tandem, dual-level load-lock and transfer station including a left-side pair of transfer stations and a right-side pair of transfer stations, the left-side pair of transfer stations and the right-side pair of transfer stations each having a first level load-lock located in a first x-y plane and a second dual-level load-lock and transfer station located in a second x-y plane, the second x-y plane being either higher or lower than the first x-y plane.

14. A semiconductor-processing tool, comprising:
a plurality of multi-station modules;
a plurality of processing stations located within each of the plurality of multi-station modules;
a vacuum-transfer module coupled to each of the multi-station modules, the vacuum-transfer module having one or more vacuum-transfer robots to transfer substrates to and from at least one of the plurality of processing stations; and
at least one additional processing-station located in the vacuum-transfer module.

15. The semiconductor-processing tool of claim 14, wherein the at least one additional processing-station is accessible by either of the one or more vacuum-transfer robots within the vacuum-transfer module.

16. The semiconductor-processing tool of claim 14, wherein the at least one additional processing-station comprises a pre-clean station.

17. The semiconductor-processing tool of claim 14, wherein the at least one additional processing-station comprises a degas station.

18. The semiconductor-processing tool of claim 14, wherein the at least one additional processing-station comprises a post-processing station.

19. The semiconductor-processing tool of claim 14, wherein the at least one additional processing-station comprises a station configured to alternate between a pre-clean station and a post-processing station.

20. The semiconductor-processing tool of claim 14, wherein the at least one additional processing-station comprises three stations.

21. The semiconductor-processing tool of claim 20, wherein the three stations comprise at least one pre-clean station and at least one degas station.

22. The semiconductor-processing tool of claim 20, wherein at least some of the plurality of processing stations are organized in a diamond-shaped arrangement in at least some of the plurality of multi-station modules.

23. A semiconductor-processing tool, comprising:
a plurality of multi-station modules;
a hybrid-arrangement of a plurality of processing stations, at least some of the hybrid-arrangement of the plurality of processing stations organized in a diamond-shaped arrangement in at least some of the plurality of multi-station modules, and a remaining portion of the hybrid-arrangement of the plurality of processing stations organized in a square-shaped arrangement in a remaining portion of the plurality of the plurality of multi-station modules not containing the processing stations organized in the diamond-shaped arrangement;
a vacuum-transfer module coupled to each of the multi-station modules, the vacuum-transfer module having one or more vacuum-transfer robots to transfer substrates to and from at least one of the plurality of processing stations; and
a plurality of additional processing-stations located in the vacuum-transfer module.

24. The semiconductor-processing tool of claim 23, further comprising at least one additional processing-station located in the vacuum-transfer module.

25. The semiconductor-processing tool of claim 23, further comprising a linear atmospheric transfer-robot located in an equipment front-end module (EFEM) of the semiconductor-processing tool.

26. The semiconductor-processing tool of claim 23, further comprising at least one maintenance-aperture feature located between at least some adjacent ones of the plurality of multi-station modules.

27. The semiconductor-processing tool of claim 23, further comprising at least one additional processing-station located in the vacuum-transfer module at a different level than the at least one additional processing-station.

28. The semiconductor-processing tool of claim 27, wherein the at least one additional processing-station is accessible by either of the one or more vacuum-transfer robots within the vacuum-transfer module.

29. The semiconductor-processing tool of claim 27, wherein the at least one additional processing-station comprises a pre-clean station.

30. The semiconductor-processing tool of claim 27, wherein the at least one additional processing-station comprises a degas station.

31. The semiconductor-processing tool of claim 27, wherein the at least one additional processing-station comprises a post-processing station.

32. The semiconductor-processing tool of claim 27, wherein the at least one additional processing-station comprises a station configured to alternate between a pre-clean station and a post-processing station.

33. The semiconductor-processing tool of claim 27, wherein the at least one additional processing-station comprises three stations.

34. The semiconductor-processing tool of claim 33, wherein the three stations comprise at least one pre-clean station and at least one degas station.

35. The semiconductor-processing tool of claim 23, further comprising a dual-level load-lock and transfer station having a first level load-lock located in a first x-y plane and a second dual-level load-lock and transfer station located in a second x-y plane, the second x-y plane being either higher or lower than the first x-y plane.

36. The semiconductor-processing tool of claim 23, further comprising a tandem, dual-level load-lock and transfer station including a left-side pair of transfer stations and a right-side pair of transfer stations, the left-side pair of transfer stations and the right-side pair of transfer stations each having a first level load-lock located in a first x-y plane and a second dual-level load-lock and transfer station located in a second x-y plane, the second x-y plane being either higher or lower than the first x-y plane.
